(19) United States
(12) Patent Application Publication
(10) Pub. No.: US 2008/0192627 A1
(43) Pub. Date: Aug. 14, 2008

(54) Method for Providing Alternative Paths as Rapid Reaction in the Failure of a Link Between Two Routing Domains

(75) Inventor: Gotz Lichtwald, Walzbachtal-Wossingen (DE)

Correspondence Address: BELL, BOYD & LLOYD, LLP, P.O. BOX 1135, CHICAGO, IL, 60690, US

(73) Assignee: NOKIA SIEMENS NETWORKS GMBH & CO KG, Muenchen, DE (DE)

(21) Appl. No.: 11/916,079

(22) PCT Filed: Jun. 1, 2006
(86) PCT No.: PCT/EP2006/062809

§ 371 Date: Nov. 30, 2007

(30) Foreign Application Priority Data
Jun. 2, 2005 (DE) 102005025421.7

(51) Int. Cl. G01R 31/08

(52) U.S. Cl. 370/228

(57) ABSTRACT

The present disclosure relates to a method for providing substitute routes in rapid response to the failure of a link between two routing domains in a packet-oriented network. According to the present disclosure, an inter-domain router determines substitute routes for fault scenarios caused by link failures. The substitute routes are stored and are regularly checked for their availability. This makes it possible to ensure, to a high degree, that a substitute route which is suitable for diverting the traffic is ready in the event of a link failing.

### FIELD OF TECHNOLOGY

The present disclosure relates to a method for providing alternative paths as a rapid reaction to the failure of a link between two routing domains in a packet-oriented network.

More specifically, the present disclosure relates to the field of Internet technologies, and the field of routing methods in packet-oriented networks, and is targeted at the transmission of data under realtime conditions.

### BACKGROUND

An important development in the field of networks at present is the convergence of voice and data networks. An important future scenario is that data, voice and video information are transmitted via a packet-oriented network, with newly developed network technologies assuring that requirement features for various classes of traffic are observed. Future networks for various types of traffic are expected to operate in packet-oriented fashion. Current development activities relate to the transmission of voice information via networks which are conventionally used for data traffic, particularly IP (Internet Protocol) based networks.

To allow voice communication via packet networks and particularly IP based networks having a quality that is equivalent to that of voice transmission via circuit-switched networks, it is necessary for quality parameters such as the delay for data packets or jitter to be kept within narrow limits. In the case of voice transmission, it is of great importance to the quality of the service provided for the delay times not to substantially exceed values of 150 milliseconds. To achieve a correspondingly short delay, work is being carried out on improved routers and routing algorithms which are intended to allow faster handling of the data packets.

In the case of routing via IP networks, a distinction is usually drawn between intra-domain and inter-domain routing. Data transmission via the Internet usually involves networks—in this context, reference is also made to subnetworks, to domains or what are known as autonomous systems—from various network operators. The network operators are responsible for the routing within the domains which come under their area of responsibility. Within these domains, they have the freedom to adapt the procedure for routing according to their own wishes as desired, just so long as it is possible to comply with quality-of-service features. The situation is different in the case of routing between different domains, where different domain operators are connected to one another. Inter-domain routing is complicated by the fact that first it is necessary to determine the best possible paths to the destination via various domains, but secondly domain operators are able to apply strategies locally which influence global calculation of optimum paths on the basis of objective criteria. By way of example, one strategy involves domains from network operators in a particular country being avoided for traffic of a certain origin. However, this strategy is now generally not known to all network operators with domains via which the traffic is routed, i.e. a network operator needs to make a local decision regarding the domain to which he forwards traffic without having complete information about the best path in terms of metrics. The strategies are frequently also referred to by the term “policies”.

For the routing between various domains, what are known as Exterior Gateway Protocols EGP are used. At present, version 4 of the Border Gateway Protocol (frequently shortened to BGP), described in more detail in RFC (Request For Comments) 1771, is usually used on the Internet. The Border Gateway Protocol is what is known as a path vector protocol. A BGP entity (the term “BGP speaker” is frequently used in English literature) is informed by its BGP neighbors about possible paths to destinations which can be reached via the respective BGP neighbor. Similarly communicated properties of the paths (path attributes) provide the BGP entity with the best respective path from its local point of view to the destinations which can be reached. The BGP protocol involves four types of messages being exchanged between BGP entities, said messages including what is known as an update message which is used to propagate path information through the entire network and which allows the network to be optimized in line with topology changes. Sending update messages usually results in the path information being adapted on all BGP entities in the network for the purpose of routing optimized in line with the locally available information. In addition, what are known as keepalive or state confirmation messages are a feature, these being used by a BGP entity to enlighten its BGP neighbors about its operability. In the absence of these messages, the BGP neighbors assume that the link to the BGP entity has been disrupted.

The propagation of topology information using the BGP protocol has the drawback that when there are frequent change indications the load which arises as a result of the messages propagated through the network in order to indicate the change is considerable, and that the network does not converge out if change messages come in too quick succession. This problem, that the network does not converge out or that the inter-domain routing does not become stable, has been addressed by what is known as the route flap damping approach. The idea of this concept is to sanction the indication of a change by a BGP neighbor. When a change message is received, the damping parameter is increased, and change reports are ignored if the damping parameter exceeds a threshold. The damping parameter decreases exponentially over time. Consequently, change reports from BGP entities are ignored so long as the damping value has not dropped below the lower threshold (reuse threshold). However, the method has the drawback that it carries the risk of a potential loss of connection, which cannot be tolerated for realtime traffic.

EP 1453250, incorporated by reference in its entirety herein, describes an approach for extending the BGP protocol by a method for rapid reaction to link failures in the case of inter-domain routing. This approach provides alternative paths, with no prior propagation of change messages through the entire network being required. A change to the routing is made only along alternative paths. This limited adjustment to the routing allows a rapid reaction to faults. In the case of prolonged faults (persistent error), it is additionally possible to perform topology adaptation in the network using the BGP protocol.

### SUMMARY

Accordingly, a method, apparatus and system is disclosed that improves the availability of alternative paths as a reaction to link failures in the case of inter-domain routing.

The present disclosure is targeted at the availability of alternative paths in the event of disruption to the inter-domain routing as a result of a link failure. Such alternative paths can be calculated using an EGP (Exterior Gateway Protocol) protocol, for example, from path information provided by neighbors and can be reserved by inter-domain routers. The presently disclosed system provides for alternative paths to be determined for error scenarios and for these alternative paths to be regularly checked for availability, so that in the event of an error it is possible to quickly redirect the traffic to a working alternative path. In this case, the inter-domain routing along this alternative path is set such that data packets which would normally be routed via the disrupted link are routed along the alternative path to their destination (e.g. provided by one or more destination network prefixes).

In this context, link failure is understood to mean any fault which interrupts the connection or the connectivity between two routing domains. A routing domain (also know as an “autonomous system” or “subnetwork”) is characterized by uniform routing within the domain. By way of example, packets within a domain are routed using the OSPF (Open Shortest Path First) protocol. In contrast, the present disclosure relates to the routing between domains (inter-domain routing), and a method for providing alternative paths being assumed in order to be able to react rapidly and more stably (in comparison with BGP topology changes) to link failures between domains. In this case, the link failure is established by a routing domain. This is done by a router in the routing domain which is equipped with protocol software for inter-domain routing. Such routers are subsequently referred to as inter-domain routers, EGP (Exterior Gateway Protocol) routers or EGP entities. In the case of the BGP (Border Gateway Protocol) protocol, reference is also made to a BGP speaker or a BGP entity. When an alternative path has been provided, a message about the link failure is propagated, but not through the entire network (as in the case of BGP) but rather only along the alternative path. Routers which receive the message adjust their inter-domain routing for routing along the alternative path. By way of example, this is done by changing routing tables from inter-domain routers associated with the domains situated on the alternative path.

Alternative paths are ascertained or determined for error scenarios relating to the inter-domain routing. This determination can be made using information distributed using an EGP protocol. In this case, it makes sense to provide at least one alternative path for each possible destination. A limitation to one alternative path for a destination can then cover all error scenarios if said alternative path is totally disjunct from the path which is to be replaced. When paths are not disjunct, it is advantageous to provide a plurality of alternative paths which cover all error scenarios relating to the destination. Ascertained alternative paths are stored and regularly (e.g. at periodic intervals) checked for their availability. Such a check can be performed using a connection setup message or test message which is sent to the respective destination. If a response message or confirmation message is returned, then the alternative path is usable or available.

Under an exemplary embodiment, a plurality of alternative paths are determined and assessed in terms of their quality. Examples of criteria for the quality are the period of time which elapses during a connection setup attempt or the number of routers crossed or passed on the path to the destination. The available bandwidth can also be used for classification. The path having the highest quality is then used in the event of an error. To determine quality, it is possible to use a weighted average which is respectively adapted when new values are determined. Such determination of an average involves what is known as the moving weighted average, for example. Determining an average reduces the influence of nonrepresentative large fluctuations in the traffic distribution.

Alternative paths for inter-domain routing which avoids link failure are routinely provided and checked for availability in line with the present disclosure. This results in increased reliability when changing over to an alternative path. Additional consideration of the quality of alternative paths is equivalent to optimizing the quality (delay, possibly bandwidth) of the reaction to error by redirecting the traffic onto an alternative path.

The present disclosure further discloses a router which is designed to communicate with other routers using an EGP protocol (EGP router) and additionally has means for carrying out the inventive method (particularly for determining alternative paths and testing alternative paths for availability). These means may comprise both hardware means (CPU, ASIC) and software means (computer routines, communication protocols).

### BRIEF DESCRIPTION OF THE DRAWINGS

The various objects, advantages and novel features of the present disclosure will be more readily apprehended from the following Detailed Description when read in conjunction with the enclosed drawings, in which:

FIG. 1 illustrates reaction based on the BGP protocol for link failure with BGP inter-domain routing;

FIG. 2 illustrates reaction to a link failure by providing an alternative path; and

FIG. 3 illustrates a network configuration with link failure and two possible alternative paths.

### DETAILED DESCRIPTION

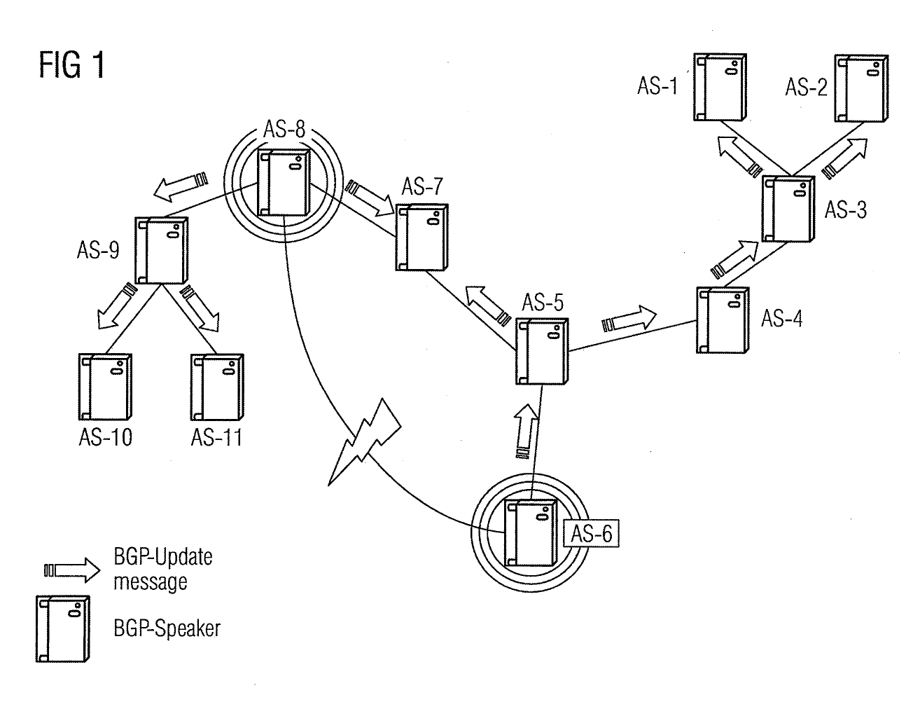

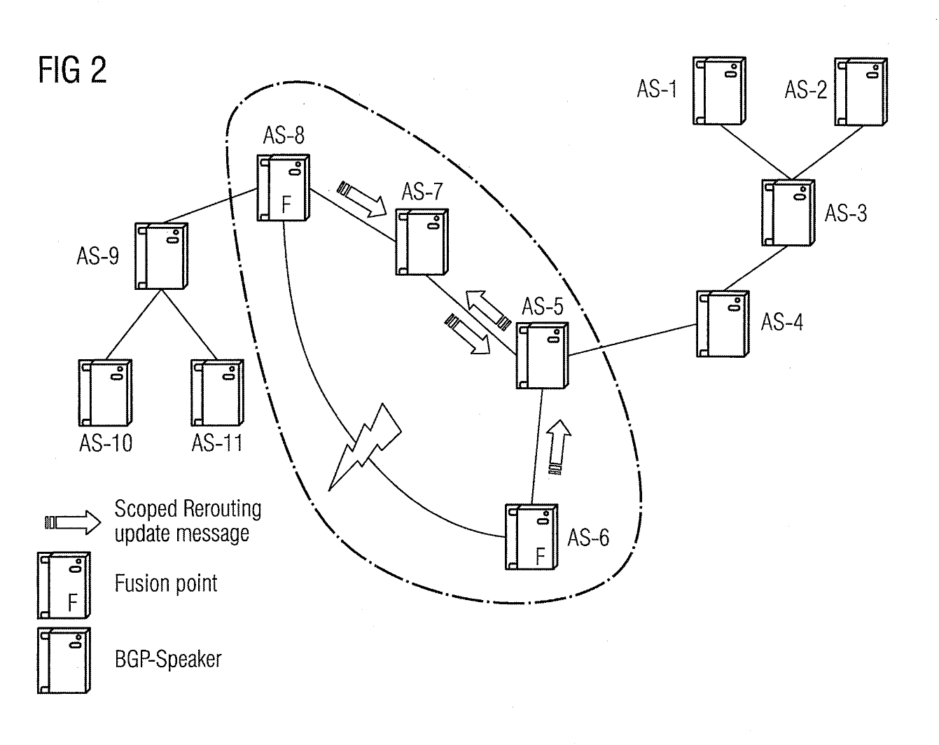

FIG. 1 and FIG. 2 are used to explain the concept of the use of alternative paths for inter-domain routing, as is also described in EP 1453250. In this context, it is assumed that the EGP protocol used is the BGP protocol.

FIG. 1 shows eleven autonomous systems or routing domains AS-1 to AS-11 and also links which connect the autonomous systems to one another. The autonomous systems communicate with one another using the BGP protocol, individual routers in the autonomous systems being equipped with appropriate protocol capabilities. In this context, reference is made to BGP speakers or BGP entities. Using these BGP entities, the autonomous systems exchange messages with one another which either confirm the stored state or communicate a change which needs to be taken into account for the routing. FIG. 1 indicates how the BGP protocol controls a reaction to a link failure. In this case, the link between the autonomous systems AS-6 and AS-8 is disrupted. As a reaction to the fault—the reaction is identified by arrows—update messages are propagated in the entire network or the eleven autonomous systems AS-1, . . . , AS-11 receive update messages which prompt them to recalculate optimum paths in terms of local metrics.

FIG. 2 shows the same networking of autonomous systems as FIG. 1. FIG. 2 shows a rapid reaction, providing an alternative path, to the link failure between the autonomous systems AS-6 and AS-8. Messages are sent to autonomous systems which are situated on alternative paths for paths which run via the failed link. The autonomous system AS-8 sends messages about the link failure to the autonomous system AS-7, which in turn sends them to the autonomous system AS-5. Since the autonomous system AS-8 can reach all the autonomous systems in the right-hand half of the figure—i.e. the autonomous systems AS-1 to AS-4 and AS-6—via the autonomous systems AS-7 and AS-5, the autonomous system AS-5 does not need to propagate the message received from AS-8 about the link failure further. Similarly, the autonomous system AS-6 sends a message to the autonomous system AS-5. This then informs the autonomous system AS-7. The link failure therefore affects the autonomous systems AS-5 to AS-8, which provide or identify alternative paths for paths running via the failed link. In contrast to the reaction using the BGP protocol as shown in FIG. 1, no messages need to be propagated over the entire network. In the figure, the autonomous systems AS-1 to AS-4 and AS-9 to AS-11 receive no messages about the link failure and do not need to make any adaptations.

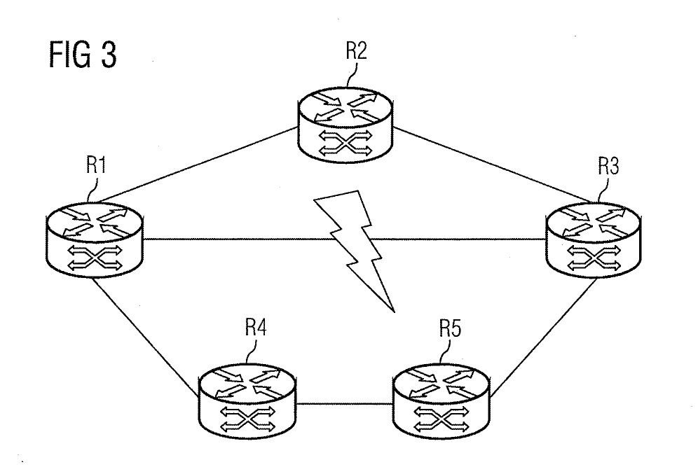

FIG. 3 shows an Internet topology under an exemplary embodiment. In this case, the routers R1-R5 are BGP routers. In addition, each router can be considered to be a separate autonomous system to simplify matters. Paths are learned using the BGP protocol. The BGP protocol is used to exchange path information (normally using the update messages of the BGP protocol; the path attribute AS Path in the update message provides a sequence for the autonomous systems which are crossed on the path). This means that paths to a destination can be learned. By way of example, it is possible to see three paths from R1 to R3 in FIG. 3, namely <R1, R3>, <R1, R2, R3> and <R1, R4, R5, R3>. For undisrupted operation, the direct path <R1, R3> is used. The other paths <R1, R2, R3> and <R1, R4, R5, R3> are learned using the BGP protocol and are stored as alternative paths. They are periodically checked for their availability and quality. To this end, a connection setup message is sent along the paths and is acknowledged to the sender again by R3. This may be a message reintroduced or recreated specifically for this purpose, e.g. a message which simulates connection setup signaling but which is not interpreted by the network entities as a genuine connection setup message. Following the acknowledgement (i.e. receipt of a response message), the alternative path is not started up as in the case of the actual connection setup; instead, the traffic is directed further along the route <R1, R3>. The router R3 measures the time for the connection setup attempt. This time is formed for the formation of an exponentially weighted average value, i.e. an average is formed from the measured values hitherto, with exponential weighting being carried out in accordance with the interval of time between the measurement and the time at which the average is formed. To classify the paths <R1, R2, R3>and <R1, R4, R5, R3>, both the average for the connection setup period and the length of the paths are used. By way of example, the criterion used may be the (possibly weighted) sum of the ratios of the two variables for the paths.

When the connection <R1, R3> has failed, there are still two possible alternative paths or FaSRo (Fast Scoped Rerouting) paths available: <R1, R2, R3> and <R1, R4, R5, R3>. On the basis of the test messages or connection setup messages, the FaSRo path <R1, R4, R5, R3> may be the better one if the routers R4 and R5 have little loading and are connected to the network using high bandwidths. For the sake of simplicity, it is assumed that the average for the connection setup period for the path <R1, R4, R5, R3> is half of that for <R1, R2, R3>. An unweighted sum of the ratios of connection setup period averages and path lengths (number of routers or autonomous systems) gives the value 1/2+4/3=11/6 for the path <R1, R4, R5, R3> and the value 2/1+3/4=11/4 for the path <R1, R2, R3>. The smaller value is obtained for the path <R1, R4, R5, R3>, which on the basis of this criterion has a higher quality and is used to redirect the traffic. In reality, more complex quality comparisons which better correspond to the actual circumstances are usually performed.

While the invention has been described with reference to one or more exemplary embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiments disclosed as the best mode contemplated for carrying out this invention, but that the invention will include all embodiments falling within the scope of the appended claims.

1-7. (canceled)

8. A method for improving the availability of alternative paths for a failure of a link between two routing domains in a packet-oriented network, comprising the steps of:
receiving data related to the failed link in one of the routing domains;
determining, via an inter-domain router, at least one alternate path to a destination in light of the failed link;
notifying the routing domains situated on the at least one alternate path of the determination;
adjusting inter-domain routing in the routing domains based on the notification until all the routing domains on the alternative path have adjusted their respective inter-domain routing line with routing on the at least one alternative path to the destination.

9. The method according to claim 8, wherein the inter-domain router regularly checks the availability of the at least one alternate path.

10. The method according to claim 9, wherein the availability is checked by a connection setup attempt.

11. The method according to claim 10, wherein the connection setup attempt comprises sending one of a connection setup message and a test message to the destination and returning a response message.

12. The method according to claim 9, wherein a plurality of alternative paths are determined, wherein the alternative paths are classified according to their quality, and the alternative path with the highest quality is started up when the failed link occurs.

13. The method according to claim 12, wherein the quality is determined in accordance with one of (1) the period of time for connection setup attempts and (2) the number of routers passed along the alternative path.

14. A system for improving the availability of alternative paths for a failure of a link between two routing domains in a packet-oriented network, comprising:
an inter-domain router that receives data related to the failed link in one of the routing domains, and determines at least one alternate path to a destination in light of the failed link, wherein the inter-domain router notifies the routing domains situated on the at least one alternate path of the determination,
wherein inter-domain routing is adjusted in the routing domains based on the notification until all the routing domains on the alternative path have adjusted their respective inter-domain routing line with routing on the at least one alternative path to the destination.
